(19) United States
(12) Patent Application Publication
(10) Pub. No.: US 2025/0190648 A1
(43) Pub. Date: Jun. 12, 2025

(54) AUTOMATED VEHICLE MARSHALING MONITORING AND CONTROL USING A DIGITAL TWIN

(71) Applicant: Ford Global Technologies, LLC, Dearborn, MI (US)

(72) Inventors: Phillip Benjamin Ring, Oak Park, MI (US); Mario Anthony Santillo, Canton, MI (US)

(73) Assignee: Ford Global Technologies, LLC, Dearborn, MI (US)

(21) Appl. No.: 18/532,362

(22) Filed: Dec. 7, 2023

(51) Int. Cl. G06F 30/20; G06T 19/00; G06T 19/20; G06V 20/54

(52) U.S. Cl. CPC G06F 30/20; G06T 19/003; G06T 19/20; G06V 20/54; G06T 2219/2004

(57) ABSTRACT

A method of monitoring a marshaling of a plurality of autonomously operated vehicles toward a waypoint including the receipt of sensor data from a plurality of visual sensors, the calculation of one or more control inputs based on the sensor data, the generation of control data using the one or more control inputs, a computer-aided design (CAD) model of the plurality of autonomously operated vehicles being marshaled toward the waypoint rendered based on the sensor data and the control data, and a digital twin updated based on the CAD model.

### FIELD

The present disclosure relates to vehicle marshaling. More specifically, the present disclosure relates to the creation of a digital twin for automated vehicle marshalling.

### BACKGROUND

The statements in this section merely provide background information related to the present disclosure and may not constitute prior art.

A digital twin model of a manufacturing environment can be used for different applications within the engineering industry. However, commercial use of the digital twin model can be fiscally tolling. Commercial use of the digital twin model is also difficult to modify and/or add information specific to a subsystem within the manufacturing environment once implemented. User interaction with the digital twin is also difficult. The present disclosure addresses these and other issues related to marshaling vehicles.

### SUMMARY

This section provides a general summary of the disclosure and is not a comprehensive disclosure of its full scope or all of its features.

The present disclosure provides a method of monitoring a marshaling of a plurality of autonomously operated vehicles toward a waypoint, the method comprising: receiving, from a plurality of visual sensors, sensor data, wherein the sensor data is associated with one or more vehicles of the plurality of autonomously operated vehicles; calculating, based on the sensor data, one or more control inputs; generating control data using the one or more control inputs; rendering, based on the sensor data and the control data, a computer-aided (CAD) model of the plurality of autonomously operated vehicles being marshaled toward the waypoint; and updating, based on the CAD model, a digital twin, wherein the digital twin digitally displays the plurality of autonomously operated vehicles being marshaled toward the waypoint to a user; wherein the sensor data comprises RGB data, depth data, point cloud data, infrared data, or a combination thereof; further comprising receiving an input from the user and controlling navigation of the digital twin in a three-dimensional mode or a virtual reality mode based on the received input; further comprising: displaying, to the user, a diagnostic text overlay associated with each vehicle of the plurality of autonomously operated vehicles, wherein the diagnostic text overlay associated with each vehicle includes a vehicle identification number, a two-dimensional location, a current status, a control input, a trim level, a respective color, waypoint, or a combination thereof; and displaying, to the user, a diagnostic text overlay associated with each of the plurality of visual sensors, wherein the diagnostic text overlay associated with each of the plurality of visual sensors includes resolution, frames per second, latency, or a combination thereof; further comprising: generating a sphere within the digital twin; activating, based on a scope of the sphere, the one or more visual sensors of the plurality of visual sensors, one or more vehicles of the plurality of autonomously operated vehicles, or a combination thereof, wherein the one or more visual sensors or the one or more vehicles are disposed within a controllable radius of the sphere; and deactivating, based on the scope of the sphere, the one or more visual sensors or the one or more vehicles disposed outside of the controllable radius of the sphere; wherein each of the plurality of visual sensors are remotely accessible by the user, such that the user can select any sensor of the plurality of sensors to view a portion of the digital twin in real-time; further comprising: initiating a corrective action associated with a vehicle of the plurality of autonomously operated vehicles, wherein the corrective action assigns a new waypoint to the vehicle; wherein updating the digital twin further comprises: generating, based on sensor data received from the plurality of visual sensors, one or more CAD models, wherein each of the one or more CAD models correspond to each of the plurality of autonomously operated vehicles; and overlaying the one or more CAD models over the rendered CAD model.

The present disclosure provides a system for monitoring a marshaling of a plurality of autonomously operated vehicles toward a waypoint, the system comprising: a server configured to: receive, from a plurality of visual sensors, sensor data, wherein the sensor data is associated with one or more vehicles of the plurality of autonomously operated vehicles, calculate, based on the sensor data, one or more control inputs, generate control data using the one or more control inputs, render, based on the sensor data and the control data, a computer-aided design (CAD) model of the plurality of autonomously operated vehicles being marshaled toward the waypoint, and update, based on the CAD model, a digital twin, wherein the digital twin digitally displays the plurality of autonomously operated vehicles being marshaled toward the waypoint to a user; the plurality of visual sensors configured to: send, to the server, the sensor data; and the plurality of autonomously operated vehicles configured to: receive, from the server, the control data; wherein the server configured to update the digital twin is further configured to: generate, based on sensor data received from the plurality of visual sensors, one or more CAD models, wherein each of the one or more CAD models correspond to each of the plurality of autonomously operated vehicles; and overlay the one or more CAD models over the rendered CAD model; wherein the system is further configured to: display, to the user, a diagnostic text overlay associated with each vehicle of the plurality of autonomously operated vehicles, wherein the diagnostic text overlay associated with each vehicle includes a vehicle identification number, a two-dimensional location, a current status, a control input, a trim level, a respective color, waypoint, or a combination thereof; and display, to the user, a diagnostic text overlay associated with each of the plurality of visual sensors, wherein the diagnostic text overlay associated with each of the plurality of visual sensors includes resolution, frames per second, latency, or a combination thereof; wherein the system is further configured to: generate a sphere within the digital twin; activate, based on a scope of the sphere, the one or more visual sensors of the plurality of visual sensors, one or more vehicles of the plurality of autonomously operated vehicles, or a combination thereof, wherein the one or more visual sensors or the one or more vehicles are disposed within a controllable radius of the sphere; deactivate, based on the scope of the sphere, the one or more visual sensors or the one or more vehicles disposed outside of the controllable radius of the sphere; wherein each of the plurality of visual sensors are remotely accessible by the user, such that the user can select any sensor of the plurality of sensors to view a portion of the digital twin in real-time; wherein the server further configured to: initiate a corrective action associated with a vehicle of the plurality of autonomously operated vehicles, wherein the corrective action assigns a new waypoint to the vehicle.

The present disclosure provides one or more non-transitory computer-readable media storing processor-executable instructions that, when executed by at least one processor, cause the at least one processor to: receive, from a plurality of visual sensors, sensor data, wherein the sensor data is associated with one or more vehicles of a plurality of autonomously operated vehicles; generate control data using the one or more control inputs; send, to one or more vehicles of the plurality of autonomously operated vehicles based on the one or more control inputs, control data; render, based on the sensor data and the control data, a computer-aided design (CAD) model of the plurality of autonomously operated vehicles being marshaled toward a waypoint; and update, based on the CAD model, a digital twin, wherein the digital twin digitally displays the plurality of autonomously operated vehicles being marshaled toward the waypoint to a user; wherein the at least one processor is further caused to: generate, based on sensor data received from the plurality of visual sensors, one or more CAD models, wherein each of the one or more CAD models correspond to each of the plurality of autonomously operated vehicles; and overlay the one or more CAD models over the rendered CAD model; wherein the at least one processor is further caused to: display, to the user, a diagnostic text overlay associated with each vehicle of the plurality of autonomously operated vehicles, wherein the diagnostic text overlay associated with each vehicle includes a vehicle identification number, a two-dimensional location, a current status, a control input, a trim level, a respective color, waypoint, or a combination thereof; and display, to the user, a diagnostic text overlay associated with each of the plurality of visual sensors, wherein the diagnostic text overlay associated with each of the plurality of visual sensors includes resolution, frames per second, latency, or a combination thereof; wherein the at least one processor is further caused to: generate a sphere within the digital twin; activate, based on a scope of the sphere, the one or more visual sensors of the plurality of visual sensors, one or more vehicles of the plurality of autonomously operated vehicles, or a combination thereof, wherein the one or more visual sensors or the one or more vehicles are disposed within a controllable radius of the sphere; and deactivate, based on the scope of the sphere, the one or more visual sensors or the one or more vehicles disposed outside of the controllable radius of the sphere; wherein each of the plurality of visual sensors are remotely accessible by the user, such that the user can select any sensor of the plurality of sensors to view a portion of the digital twin in real-time; wherein the at least one processor is further caused to: initiate a corrective action associated with a vehicle of the plurality of autonomously operated vehicles, wherein the corrective action assigns a new waypoint to the vehicle.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 illustrates a system for automated vehicle marshaling in accordance with various implementations;

FIG. 2 illustrates an example vehicle distributed by the system shown in FIG. 1 in accordance with various implementations;

FIG. 3 is a block diagram illustrating a communication architecture within the system shown in FIG. 1 in accordance with various implementations;

FIG. 4 illustrates an example display of a digital twin associated with the system shown in FIG. 1 in accordance with various implementations;

FIG. 5 illustrates an embodiment of the example display of the digital twin associated with the system shown in FIGS. 1 and 4 in accordance with various implementations; and

FIG. 6 is a flowchart illustrating an example method for a creation of a digital twin in accordance with various implementations.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The present disclosure provides a means for a creation of a digital twin, particularly for use in vehicle marshaling. For example, the present disclosure provides a system that allows for viewing the digital twin in both a three-dimensional mode and a virtual reality mode. As another example, each of the three-dimensional mode and the virtual reality mode provide a user with the ability to navigate through the digital twin. The user is also provided with the ability to remotely control the system and any vehicle of one or more vehicles therein. The digital twin also provides for any number of diagnostic information to be displayed upon any portion of the digital twin, such as one or more visual sensors and/or the one or more vehicles.

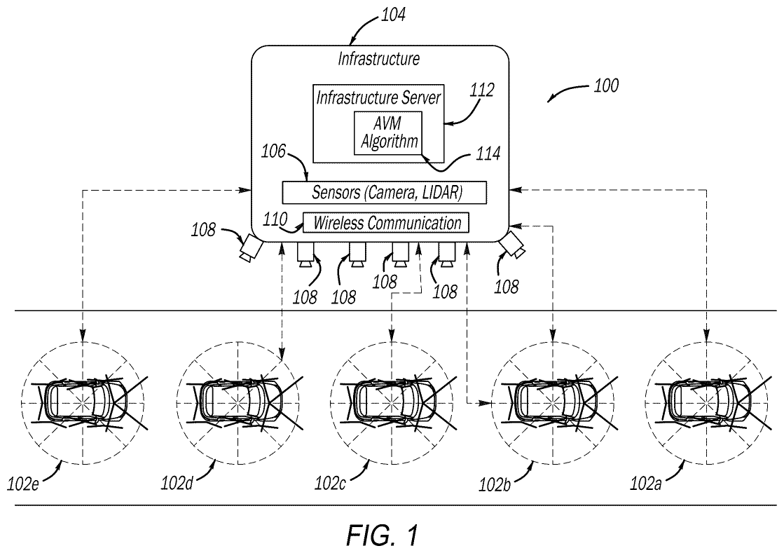

Referring now to FIG. 1, there is shown a system 100 (e.g., an automated vehicle marshaling (AVM) system) for the distribution of autonomous and semi-autonomous vehicles 102 (e.g., one or more vehicles 102a-102e) for example, situated in a parking lot and/or factory floor. The system 100 includes an infrastructure server 104. The infrastructure server 104 further includes a sensor component 106 that communicates with a set of infrastructure sensors 108 such as, for example, one or more cameras, lidar, radar, and/or ultrasonic devices. The sensors 108 monitor the movement of the vehicles 102 as the vehicles 102 move through, for example, a factory floor and/or parking lot. The infrastructure server 104 also includes a wireless communication component 110 that provides for communication between the infrastructure server 104 and the vehicles 102. Additionally, the infrastructure server 104 includes an infrastructure controller 112. The infrastructure controller 112 is configured to centrally control the operation of each of the vehicles 102. For example, the operation of each of the vehicles 102 include propulsion, braking, and steering of the vehicles 102. It is understood that the infrastructure controller 112 may be disposed within the infrastructure server 104 or externally located relative to the infrastructure server 104. The infrastructure controller 112 includes an AVM software module 114 that is configured to facilitate for the infrastructure controller 112 to communicate with a vehicle controller 200 associated with each of the vehicles 102.

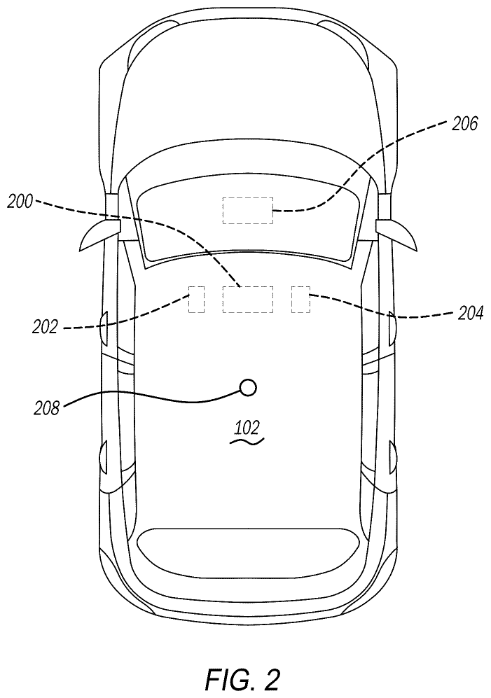

Referring further to FIG. 2, in various forms, the vehicles 102 may be powered in a variety of ways, for example, with an electric motor and/or an internal combustion engine. The vehicles 102 may be any type of vehicle powered by an electric motor and/or an internal combustion engine such as a car, a truck, a robot, a plane and/or a boat, as non-limiting examples. The vehicles 102 include the vehicle controller 200, one or more actuators 202, a plurality of on-board sensors 204, and a human machine interface (HMI) 206. The vehicles 102 have a reference point 208, that is, a specified point within the space defined by a vehicle body, for example, a geometrical center point at which respective longitudinal and lateral center axes of the vehicle 102 intersect. The reference point 208 identifies the location of the vehicles 102, for example, a point at which the vehicles 102 are located as the vehicles 102 navigate toward a waypoint.

The vehicle controller 200, in some examples, is configured or programmed to control the operation of one or more of vehicle brakes, propulsion (e.g., control of acceleration in the vehicle by controlling one or more of an internal combustion engine, electric motor, hybrid engine, etc.), steering, climate control, interior and/or exterior lights, etc., as well as to determine whether and when the vehicle controller 200, as opposed to a human operator, is to control such operations. Additionally, the vehicle controller 200 is programmed to determine whether and when a human operator is to control such operations. It is understood that any of the operations associated with the vehicles 102 may be facilitated via an automated, a semi-automated, or a manual mode. For example, the automated mode may facilitate for any of the operations to be fully controlled by the vehicle controller 200 without the aid of a user. As another example, the semi-automated mode may facilitate for any of the operations to be at least partially controlled by the vehicle controller 200 and/or the user. As a further example, the manual mode may facilitate for any of the operations to be fully controlled by the user.

The vehicle controller 200 includes or may be communicatively coupled to (for example, via a vehicle communications bus) one or more processors, for example, controllers or the like included in the vehicles 102 for monitoring and/or controlling various vehicle controllers, such as a powertrain controller, a brake controller, a steering controller, etc. The vehicle controller 200 is generally arranged for communications on a vehicle communication network that can include a bus in the vehicle 102 such as a controller area network (CAN) or the like, and/or other wired and/or wireless mechanisms.

Via a vehicle network, the vehicle controller 200 transmits messages to various devices in the vehicles 102 and/or receives messages from the various devices, for example, the one or more actuators 202, the HMI 206, etc. Alternatively, or additionally, in cases where the vehicle controller 200 includes multiple devices, the vehicle communication network is utilized for communications between devices represented as the vehicle controller 200 in this disclosure. Further, as discussed below, various other controllers and/or sensors provide data to the vehicle controller 200 via the vehicle communication network.

In addition, the vehicle controller 200 is configured for communicating through a wireless vehicular communication interface with other traffic objects (for example, vehicles, infrastructures, pedestrians, etc.), such as, via a vehicle-to-vehicle communication network. The vehicle controller 200 is also configured for communicating through a vehicle-to-infrastructure communication network, such as communicating with the infrastructure controller 112 of the infrastructure server 104. The vehicular communication network represents one or more mechanisms by which the vehicle controller 200 of the vehicles 102 communicate with other traffic objects, and may be one or more of wireless communication mechanisms, including any desired combination of wireless (e.g., cellular, wireless, satellite, microwave, and radio frequency) communication mechanisms and any desired network topology (or topologies when multiple communication mechanisms are utilized). Examples of vehicular communication networks include, among others, cellular, Bluetooth®, IEEE 802.11, dedicated short range communications (DSRC), and/or wide area networks (WAN), including the Internet, providing data communication services.

The vehicle actuators 202 are implemented via circuits, chips, or other electronic and/or mechanical components that can actuate various vehicle subsystems in accordance with appropriate control signals. The actuators 202 may be used to control braking, acceleration, and/or steering of the vehicles 102. The vehicle controller 200 can be programmed to actuate the vehicle actuators 202 including propulsion, steering, and/or braking based on the planned acceleration or deceleration of the vehicles 102.

The sensors 204 include a variety of devices to provide data to the vehicle controller 200. For example, the sensors 204 may include object detection sensors such as lidar sensor(s) disposed on or in the vehicles 102 that provide relative locations, sizes, and shapes of one or more targets surrounding the vehicles 102, for example, additional vehicles, bicycles, pedestrians, robots, drones, etc., travelling next to, ahead, and/or behind the vehicle 102. As another example, one or more of the sensors can be radar sensors fixed to one or more bumpers of the vehicles 102 that may provide locations of the target(s) relative to the location of each of the vehicles 102.

The object detection sensors may include a camera sensor, for example, to provide a front view, side view, rear view, etc., providing images from an area surrounding the vehicles 102. For example, the vehicle controller 200 may be programmed to receive sensor data from a camera sensor(s) and to implement image processing techniques to detect a road, infrastructure elements, etc. The vehicle controller 200 may be further programmed to determine a current vehicle location based on location coordinates, for example, GPS coordinates, received from the vehicles 102 and indicative of a location of the vehicles 102 location from a GPS sensor.

The HMI 206 is configured to receive information from a user, such as a human operator, during operation of the vehicles 102. Moreover, the HMI 206 is configured to present information to the user, such as, an occupant of one or more of the vehicles 102. In some variations, the vehicle controller 200 is programmed to receive destination data, for example, location coordinates, from the HMI 206.

Accordingly, the vehicles 102 can be autonomously guided toward a waypoint using a combination of the infrastructure sensors 108 and the vehicle sensors (e.g., the onboard sensors 204). Routing can be done using vehicle location, distance to travel, queue in line for vehicle marshaling, etc. Vehicles 102 requiring additional charge/fuel can be prepped ahead of joining the queue. Other vehicles 102 destined to a particular waypoint operate in the same way, so that movement of an entire fleet can be coordinated. The movements of the entire fleet coordinates through a central fleet-management system that directs all traffic and logistics from an assembly plant to the waypoint. For example, the entire fleet can be organized in a pre-sorted order.

The centralized fleet-management application in various examples has complete knowledge of the vehicles 102 in its control (for example, current location, destination, special notes, etc.), which adds accountability and traceability to the distribution process. The fleet-management is coordinated within and/or across sites to optimize delivery timing of each vehicle 102 to the waypoint. A number of logistics applications can be used, which may involve a combination of an infrastructure sensing system integrated with a traffic-management algorithm to queue and deconflict vehicles in real-time. Accordingly, the fleet-management application queues vehicles 102 based on unique characteristics (how far does the vehicle 102 need to travel, what traffic is along the route, when does the vehicle 102 need to get there to line up in the correct order, etc.).

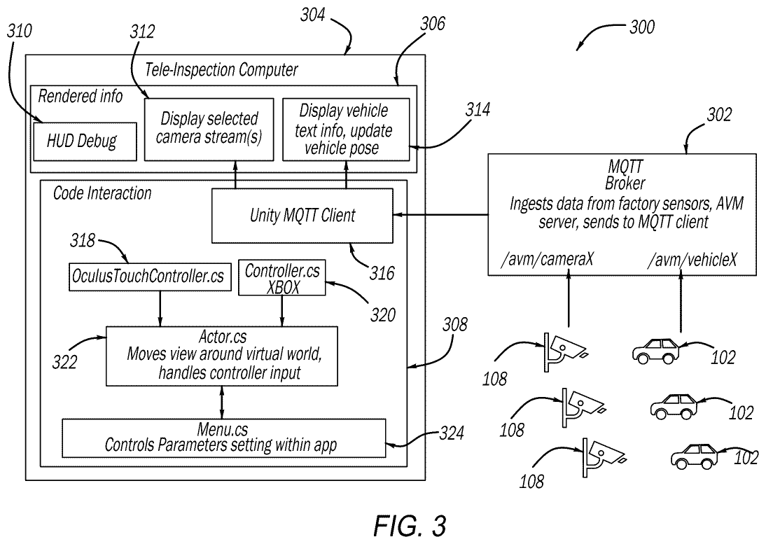

Referring to FIG. 3, a flowchart 300 of communication, associated with the system 100, between the infrastructure sensors 108, the one or more vehicles 102 (e.g., one or more vehicles 102a-102e), a Message Queuing Telemetry Transport (MQTT) broker 302, and a tele-inspection computer 304 (e.g., a user device) is illustrated. More specifically, each of the infrastructure sensors 108 communicate with the MQTT broker 302. Each of the one or more vehicles 102 also communicate with the MQTT broker 302. As an example, the MQTT broker 302 receives data from both of the infrastructure sensors 108 and the one or more vehicles 102. It is understood, however, that the MQTT broker 302 can receive data from any component associated with the marshaling of the one or more vehicles 102.

The tele-inspection computer 304 is generally comprised of a rendered information section 306 and a code interaction section 308. The rendered information section 306 includes a heads-up display (HUD) debug 310, a first display 312, and a second display 314. The first display 312 is a display of one or more selected camera streams. It is understood that the first display 312 may display any information associated with the one or more camera streams. The second display 314 is a display of vehicle textual information and/or an update on a vehicle pose. However, it is understood that the second display 314 may display any information associated with the vehicles 102.

The code interaction section 308 includes a unity MQTT client 316 (e.g., a rendering engine), a virtual reality controller 318, a controller 320, an actor control panel 322, and/or a menu control panel 324. The unity MQTT client 316 communicates with the MQTT broker 302. For example, the unity MQTT client 316 receives data from the MQTT broker 302. As another example, the unity MQTT client 316 receives data related to both of the infrastructure sensors 108 and/or the one or more vehicles 102. As an additional example the MQTT broker 302 is disposed within the system 100 (e.g., within the infrastructure server 104).

A digital twin is created by the importation of a computer-aided design (CAD) model of the system 100, with the exception of any dynamic objects. It is understood that the initial CAD model is imported from the MQTT broker 302 and is a static, digital, representation of the physical infrastructure of a manufacturing facility. For example, a computer-aided design (CAD) model is imported into the unity MQTT client 316. As another example, the infrastructure sensors 108 are included in the initial CAD model and are distributed at varying intervals within the system 100. For example, the infrastructure sensors 108 can be distributed at every 10-meter radius relative to the path followed by the one or more vehicles 102 within the system 100. However, it is understood that the infrastructure sensors 108 can be distributed at any frequency within the system 100.

The infrastructure sensors 108 monitor the path followed by the one or more vehicles 102 and communicates sensor data associated with a pose (i.e., location and/or orientation) of the vehicles 102 to the infrastructure controller 112 as they pass by the infrastructure sensors' 108 field of view. Based on the sensor data, additional CAD models representing the vehicles 102 are imported and overlain over the initial CAD model of the infrastructure of the manufacturing facility. Updates to the pose of the vehicles 102 are provided by the infrastructure sensors 108 as the vehicles 102 are transported through the manufacturing facility, thereby facilitating for the augmentation of the digital twin model.

In an embodiment, the CAD model emulates the one or more vehicles 102 in predicted locations within the system 100. As another example, the CAD model emulates the one or more vehicles 102 in locations determined by the infrastructure sensors 108 within the system 100. It is understood that the emulation of the one or more vehicles 102 may either be in real-time based on actual movement of each vehicle of the one or more vehicles 102 or slightly delayed based on previously held positions of each vehicle of the one or more vehicles 102. Regardless of how the one or more vehicles 102 are emulated within the CAD model, a user of the digital twin can observe the one or more vehicles 102 travel throughout the system 100 (e.g., the factory and/or parking lot).

The unity MQTT client 316 can send data associated with different text overlays to the second display 314 associated with any of the one or more vehicles 102 as the one or more vehicles 102 travel throughout the system 100. For example, the text overlays can include any type of identifying information associated with each of the one or more vehicles 102 such as at least a trim level and/or a respective color, or other information. The MQTT broker 302 can send diagnostic information to the unity MQTT client 316. For example, the diagnostic information can be displayed as additional data in the text overlay. It is understood that the diagnostic information includes at least a vehicle identification number (VIN), a pose of the one or more vehicles 102 (i.e., a two-dimensional location and heading and/or orientation of the one or more vehicles 102), a current status of the one or more vehicles 102, speed, and/or a control input. It is further understood that the diagnostic information includes any type of identifying information associated with the one or more vehicles 102. For example, the 2D location can be a coordinate relative to a predicted location of the one or more vehicles 102. As another example, the system 100 can predict the location of the one or more vehicles 102. As a further example, the control input can be a speed and/or a steering trajectory of the one or more vehicles 102. The unity MQTT client 316 can send data associated with different text overlays to the first display 312 associated with any of the infrastructure sensors 108. It is understood that the diagnostic information, which can be displayed as additional data in the text overlay, includes at least a resolution, frames per second (FPS), and/or latency. It is further understood that the diagnostic information includes any type of identifying information associated with any of the infrastructure sensors 108. As an example, the HUD debug 310 is a tool that monitors the diagnostic information and operates to mitigate any issues that may be indicated within the diagnostic information.

The tele-inspection computer 304 is configured in one or more examples to cause the digital twin to be displayed in a three-dimensional (3D) mode. For example, the user can use the controller 320 to navigate through the digital twin so that the user may inspect areas of interest within the digital twin. As another example, the controller 320 may be a keyboard. As a further example, a mouse associated with the keyboard can allow the controller 320 to control an actor control panel 322 configured to facilitate for the user to navigate through the digital twin and/or receive the user's input. As an additional example, the mouse associated with the keyboard can allow the controller 320 to control the menu control panel 324 configured to control parameter settings within the digital twin application. As an additional example, the tele-inspection computer 304 can cause the digital twin to be displayed in a virtual reality mode. The user can use a headset attached to a computer so that the user can control, via a controller and/or the user's hands, to navigate through the digital twin so that the user may inspect areas of interest within the digital twin, for example. As an additional example, the headset may be wirelessly attached to the computer or attached to the computer via a wire. Furthermore, the user can control the digital twin within a controller settings option that may be “in-engine” that is associated with the tele-inspection computer 304. It is understood that the tele-inspection computer 304 can cause the digital twin to be displayed in either the 3D mode or the virtual reality mode, wherein each of the 3D mode or the virtual reality mode is switchable within a single program displayed at the tele-inspection computer 304.

The user can navigate the digital twin to control which camera streams are shown in view. For example, the user can select one or more of the infrastructure sensors 108 to limit the stream displayed in the digital twin. As another example, in the case wherein the digital twin is displayed in the virtual reality mode, the user can point to a camera to change any settings associated with the camera such as RGB, depth image, and/or point cloud. As a further example, in the case wherein the digital twin is displayed in the 3D mode, the user can navigate a settings menu with the controller 320 to change any settings associated with the camera such as RGB, depth image, and/or point cloud. It is understood that the point cloud will appear in 3D. As an additional example, in the case wherein the digital twin is displayed in a 2D mode, a plane is placed along a frustrum of the camera with the 2D stream applied to the frustrum.

The system 100 is configured to mitigate a fault associated with the marshaling of the one or more vehicles 102. For example, the system 100 will identify or expose options for stopping and/or restarting the system 100 in in the case wherein the fault is present. As an additional example, the system 100 can send one or more commands and/or signals to the one or more vehicles 102 in the case wherein the fault is present. The system 100 can also send one or more commands and/or signals to the one or more vehicles 102 in the case wherein a trajectory of the path the one or more vehicles 102 are traveling along has deviated relative to an original waypoint. It is understood, however, that the system 100 can send one or more commands and/or signals to the one or more vehicles 102 at any time regardless of whether a fault is present. As an example, a virtual e-stop is provided to the user so that the user may select whether to stop or restart the functionality of the digital twin.

As another example, the user can control the one or more vehicles 102 within the digital twin using a keyboard, a controller, a steering wheel, or a combination thereof. As an additional example, the user may remotely control the one or more vehicles 102 via the digital twin that effectuates actual control of the one or more vehicles 102 within the system 100. In another embodiment, the user can inspect certain aspects of the system 100 not displayed and/or captured via the digital twin by remotely connecting to a robot on the floor (e.g., the parking lot floor or factory floor) of the system 100.

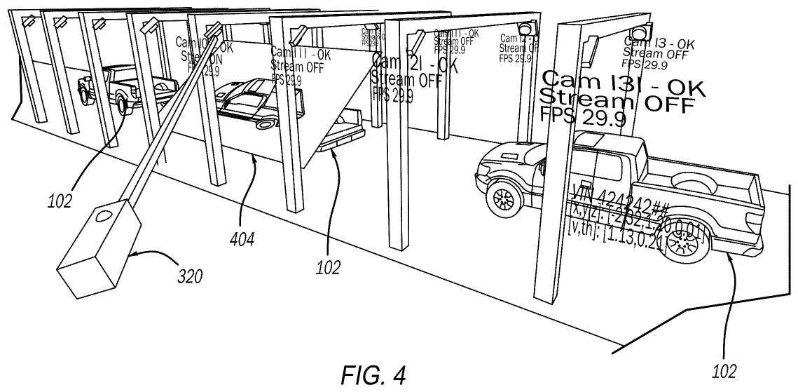

FIG. 4 is illustrative of a 3D display 400 of the digital twin. For example, the digital twin depicts one or more areas of interest within the system 100. For example, the digital twin may depict a particular vehicle(s) (e.g., the one or more vehicles 102) and/or one or more particular areas of interest within the system 100 (e.g., a particular area of interest within a factory). As another example, a plurality of visual sensors (e.g., the infrastructure sensors 108) are distributed at a plurality of locations within the system 100. As an additional example, a text overlay 402 may be displayed upon each of the plurality of visual sensors such as resolution, FPS, latency, or a combination thereof. As a further example, a text overlay 404 may be displayed upon each of the one or more vehicles such as a VIN, a 2D location, a current status, a control input, a trim level, a respective color, waypoint, or a combination thereof.

Additionally, superimposition of the sensor data and/or LIDAR data received from the infrastructure sensors 108 may cause a plane or a voxel grid 404 to be placed in a position associated with a CAD model of any of the vehicles 102. It is understood that the plane or the voxel grid 404 may be placed in a position associated with the CAD model of anything reproduced within the digital twin model, for example. Furthermore, the controller 320 is illustrated as pointed towards a particular infrastructure sensor of the infrastructure sensors 108 so that the user may cause for the infrastructure sensor to toggle ON or OFF. However, it is understood that the controller 320 may be pointed at any of the infrastructure sensors 108 to activate a response.

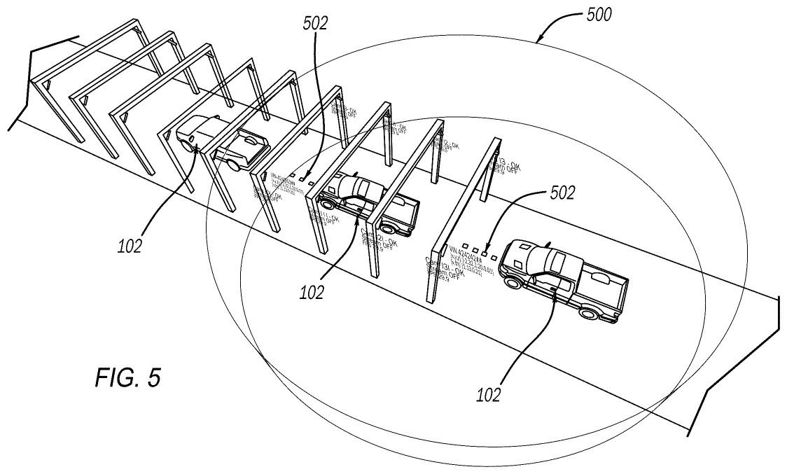

FIG. 5 illustrates an instance where the user can specify a sphere 500 within the digital twin. It is understood that the sphere 500 is indicative of a circular or spherical area within the digital twin. For example, the user can specify any area within the digital twin by using any spatial measure such as an arc-radius or any type of polygon. As another example, the sphere 500 may have a controllable radius within which a stream from one or more cameras of the infrastructure sensors 108 can be started. As another example, as the user navigates the digital twin, the sphere 500 moves also. Devices present within a scope of the sphere 500 are activated (e.g., turned ON) and the devices not present within the scope of the sphere 500 are deactivated (e.g., turned OFF). For example, the user can specific a particular vehicle of the one or more vehicles 102 so that the scope of the sphere 500 may be limited to areas around the particular vehicle. As an additional example, the user may navigate the digital twin through a scope, or field-of-view, of any shape and is not limited to a sphere. As a further example, vehicles 102 present within the scope of the sphere 500 are able to be updated and/or rendered while vehicles 102 outside the scope of the sphere 500 are not able to be updated and/or rendered. The vehicles 102 outside the scope of the sphere 500 are grayed out and have a decay period of any time period, after which the vehicles 102 outside the scope of the sphere 500 will have been removed entirely from the second display 314. Additionally, positional marks 502 may be placed in front of the each of the vehicles 102 indicating a trail of a future waypoint of the particular vehicle.

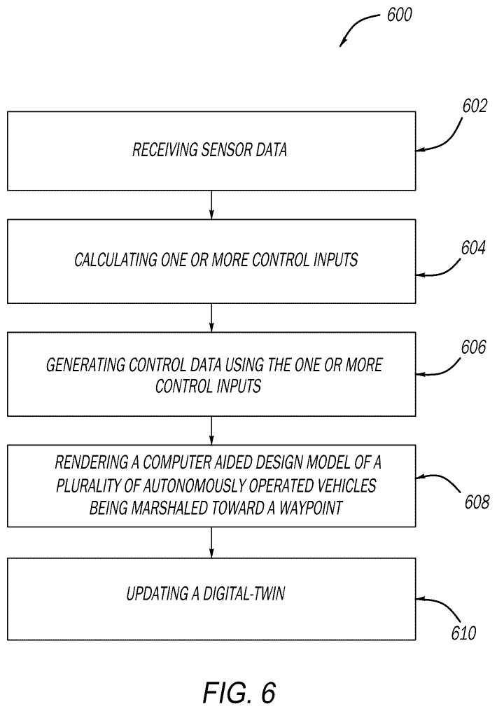

FIG. 6 is a flowchart illustrating an example method 500 of monitoring a marshaling of a plurality of autonomously operated vehicles toward a waypoint. It is understood that the marshaling of the plurality of autonomously operated vehicles may be monitored as the plurality of autonomously operated vehicles are transported along a path based on a set of commands. For example, the set of commands include at least speed information, heading information, acceleration information, braking information, or a combination thereof. It is understood that the set of commands include any type of marshaling-related information associated with the plurality of autonomously operated vehicles. At step 602 sensor data is received. For example, the sensor data is received from a plurality of visual sensors (e.g., the infrastructure sensors 108). As another example, the sensor data is associated with one or more vehicles of the plurality of autonomously operated vehicles. It is understood that the sensor data comprises at least RGB data, depth data, point cloud data, infrared data, or a combination thereof. It is further understood that the sensor data may include any type of sensor-based data. As an additional example, each of the plurality of visual sensors are remotely accessible by the user, such that the user can select any sensor of the plurality of sensors to view a portion of the digital twin in real-time.

At step 604, one or more control inputs are calculated. The one or more control inputs can include at least one or more waypoints, an array of velocity commands, an array of steer commands, or a combination thereof. It is understood that the one or more control inputs includes any positional and/or directional information associated with the vehicles 102. The one or more control inputs are calculated on the infrastructure server 104 and can then be distributed to each of the vehicles 102. At step 606 control data is generated. For example, the control data is generated using the one or more control inputs. At step 608 a CAD model of the plurality of autonomously operated vehicles being marshaled toward the waypoint is rendered. For example, the 3D model is rendered based on the sensor data. As an example, the CAD model is rendered based on the sensor data received from at least one visual sensor of the plurality of visual sensors that is actively streaming sensor data to the infrastructure server 104. As another example, the CAD model is rendered based on the control data. As a further example, the CAD model is rendered based on the sensor data and/or the control data. As an example, the control data indicates the heading and heading and/or orientation of the vehicles 102.

At step 610 a digital twin is updated. For example, the digital twin is updated based on the CAD model. As an additional example, the updates to the CAD model are based on the pose of the vehicles 102 provided by the infrastructure sensors 108 as the vehicles 102 are transported through the manufacturing facility, thereby facilitating for the augmentation of the digital twin model. As another example, the digital twin digitally displays the plurality of autonomously operated vehicles being marshaled toward the waypoint to a user. In an embodiment, an input from the user is received. For example, navigation of the digital twin is controlled in a 3D mode. As another example, the navigation of the digital twin is controlled in a virtual reality mode. Regardless of whether the navigation of the digital twin is controlled in a 3D mode or a virtual reality mode, the navigation of the digital twin is based on the received input. As an example, one or more CAD models are generated. For example, the one or more CAD models are generated based on sensor data. As an additional example, the sensor data is received from the plurality of visual sensors. As a further example, each of the one or more CAD models correspond to each of the plurality of autonomously operated vehicles. The one or more CAD models are overlain over the rendered CAD model, for example.

In another embodiment, a diagnostic text overlay associated with each vehicle of the plurality of autonomously operated vehicles is displayed. For example, the diagnostic text overlay associated with each vehicle of the plurality of autonomously operated vehicles is displayed to the user. It is understood that the diagnostic text overlay associated with each vehicle includes at least a VIN, a pose (i.e., a two-dimensional location and heading and/or orientation of the one or more vehicles 102), a current status, a control input, a trim level, a respective color, waypoint, or a combination thereof. It is further understood that the diagnostic text overlay associated with each vehicle of the plurality of autonomously operated vehicles includes any type of identifying information associated with each vehicle. A diagnostic text overlay is also associated with each of the plurality of visual sensors is displayed. For example, the diagnostic text overlay is associated with each of the plurality of visual sensors is displayed to the user. It is understood that the diagnostic text overlay associated with each of the plurality of visual sensors includes at least a resolution, FPS, latency, or a combination thereof. It is further understood that the diagnostic text overlay associated with each of the plurality of visual sensors includes any type of identifying information associated with each of the plurality of visual sensors.

In yet another embodiment, a corrective action is initiated associated with a vehicle of the plurality of autonomously operated vehicles. For example, the corrective action assigns a new waypoint to the vehicle. As another example, the corrective action is initiated based on a fault code associated with the vehicle of the plurality of vehicles. In a further embodiment, a computer-aided design is uploaded. For example, the CAD model is uploaded based on the physical infrastructure of the manufacturing facility. As a further example, additional CAD models are uploaded based on the pose of the plurality of autonomously operated vehicles registered by the infrastructure controller 112. As another example, the computer-aided design replicates an automated vehicle inspection module.

In an additional embodiment, a sphere is generated within the digital twin. For example, one or more visual sensors of the plurality of visual sensors are activated. As another example, one or more vehicles of the plurality of autonomously operated vehicles are activated. As a further example, the one or more visual sensors and the one or more vehicles are activated. As an additional example, the one or more visual sensors and/or the one or more vehicles are activated in an instance wherein the one or more visual sensors and/or the one or more vehicles are disposed within a controllable radius of the sphere. As another example, the one or more visual sensors and/or the one or more vehicles are deactivated in an instance wherein the one or more visual sensors and/or the one or more vehicles are disposed outside of the controllable radius of the sphere. It is understood that both the activation and the deactivation of the one or more visual sensors and/or the one or more vehicles is based on a scope of the sphere.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method of monitoring a marshaling of a plurality of autonomously operated vehicles toward a waypoint, the method comprising:
receiving, from a plurality of visual sensors, sensor data, wherein the sensor data is associated with one or more vehicles of the plurality of autonomously operated vehicles;
calculating, based on the sensor data, one or more control inputs;
generating control data using the one or more control inputs;
rendering, based on the sensor data and the control data, a computer-aided design (CAD) model of the plurality of autonomously operated vehicles being marshaled toward the waypoint; and
updating, based on the CAD model, a digital twin, wherein the digital twin digitally displays the plurality of autonomously operated vehicles being marshaled toward the waypoint to a user.

2. The method of claim 1, wherein the sensor data comprises RGB data, depth data, point cloud data, infrared data, or a combination thereof.

3. The method of claim 1, further comprising:
receiving an input from the user; and
controlling navigation of the digital twin in a three-dimensional mode or a virtual reality mode based on the received input.

4. The method of claim 1, further comprising:
displaying, to the user, a diagnostic text overlay associated with each vehicle of the plurality of autonomously operated vehicles, wherein the diagnostic text overlay associated with each vehicle includes a vehicle identification number, a two-dimensional location, a current status, a control input, a trim level, a respective color, waypoint, or a combination thereof; and
displaying, to the user, a diagnostic text overlay associated with each of the plurality of visual sensors, wherein the diagnostic text overlay associated with each of the plurality of visual sensors includes resolution, frames per second, latency, or a combination thereof.

5. The method of claim 1, further comprising:
generating a sphere within the digital twin;
activating, based on a scope of the sphere, the one or more visual sensors of the plurality of visual sensors, one or more vehicles of the plurality of autonomously operated vehicles, or a combination thereof, wherein the one or more visual sensors or the one or more vehicles are disposed within a controllable radius of the sphere; and
deactivating, based on the scope of the sphere, the one or more visual sensors or the one or more vehicles disposed outside of the controllable radius of the sphere.

6. The method of claim 1, wherein each of the plurality of visual sensors are remotely accessible by the user, such that the user can select any sensor of the plurality of sensors to view a portion of the digital twin in real-time.

7. The method of claim 1, further comprising:
initiating a corrective action associated with a vehicle of the plurality of autonomously operated vehicles, wherein the corrective action assigns a new waypoint to the vehicle.

8. The method of claim 1, wherein updating the digital twin further comprises:
generating, based on sensor data received from the plurality of visual sensors, one or more CAD models, wherein each of the one or more CAD models correspond to each of the plurality of autonomously operated vehicles; and
overlaying the one or more CAD models over the rendered CAD model.

9. A system for monitoring a marshaling of a plurality of autonomously operated vehicles toward a waypoint, the system comprising:
a server configured to:
receive, from a plurality of visual sensors, sensor data, wherein the sensor data is associated with one or more vehicles of the plurality of autonomously operated vehicles,
calculate, based on the sensor data, one or more control inputs,
generate control data using the one or more control inputs,
render, based on the sensor data and the control data, a computer-aided design (CAD) model of the plurality of autonomously operated vehicles being marshaled toward the waypoint, and
update, based on the CAD model, a digital twin, wherein the digital twin digitally displays the plurality of autonomously operated vehicles being marshaled toward the waypoint to a user;
the plurality of visual sensors configured to:
send, to the server, the sensor data; and
the plurality of autonomously operated vehicles configured to:
receive, from the server, the control data.

10. The system of claim 9, wherein the server configured to update the digital twin is further configured to:
generate, based on sensor data received from the plurality of visual sensors, one or more CAD models, wherein each of the one or more CAD models correspond to each of the plurality of autonomously operated vehicles; and
overlay the one or more CAD models over the rendered CAD model.

11. The system of claim 9, wherein the system is further configured to:
display, to the user, a diagnostic text overlay associated with each vehicle of the plurality of autonomously operated vehicles, wherein the diagnostic text overlay associated with each vehicle includes a vehicle identification number, a two-dimensional location, a current status, a control input, a trim level, a respective color, waypoint, or a combination thereof; and
display, to the user, a diagnostic text overlay associated with each of the plurality of visual sensors, wherein the diagnostic text overlay associated with each of the plurality of visual sensors includes resolution, frames per second, latency, or a combination hereof.

12. The system of claim 9, wherein the system is further configured to:
generate a sphere within the digital twin;
activate, based on a scope of the sphere, the one or more visual sensors of the plurality of visual sensors, one or more vehicles of the plurality of autonomously operated vehicles, or a combination thereof, wherein the one or more visual sensors or the one or more vehicles are disposed within a controllable radius of the sphere; and
deactivate, based on the scope of the sphere, the one or more visual sensors or the one or more vehicles disposed outside of the controllable radius of the sphere.

13. The system of claim 9, wherein each of the plurality of visual sensors are remotely accessible by the user, such that the user can select any sensor of the plurality of sensors to view a portion of the digital twin in real-time.

14. The system of claim 9, wherein the server further configured to:
initiate a corrective action associated with a vehicle of the plurality of autonomously operated vehicles, wherein the corrective action assigns a new waypoint to the vehicle.

15. One or more non-transitory computer-readable media storing processor-executable instructions that, when executed by at least one processor, cause the at least one processor to:
receive, from a plurality of visual sensors, sensor data, wherein the sensor data is associated with one or more vehicles of a plurality of autonomously operated vehicles;
generate control data using the one or more control inputs;
send, to one or more vehicles of the plurality of autonomously operated vehicles based on the one or more control inputs, control data;
render, based on the sensor data and the control data, a computer-aided design (CAD) model of the plurality of autonomously operated vehicles being marshaled toward a waypoint; and
update, based on the CAD model, a digital twin, wherein the digital twin digitally displays the plurality of autonomously operated vehicles being marshaled toward the waypoint to a user.

16. The one or more non-transitory computer-readable media of claim 15, wherein the at least one processor is further caused to:
generate, based on sensor data received from the plurality of visual sensors, one or more CAD models, wherein each of the one or more CAD models correspond to each of the plurality of autonomously operated vehicles; and
overlay the one or more CAD models over the rendered CAD model.

17. The one or more non-transitory computer-readable media of claim 15, wherein the at least one processor is further caused to:
display, to the user, a diagnostic text overlay associated with each vehicle of the plurality of autonomously operated vehicles, wherein the diagnostic text overlay associated with each vehicle includes a vehicle identification number, a two-dimensional location, a current status, a control input, a trim level, a respective color, waypoint, or a combination thereof; and
display, to the user, a diagnostic text overlay associated with each of the plurality of visual sensors, wherein the diagnostic text overlay associated with each of the plurality of visual sensors includes resolution, frames per second, latency, or a combination thereof.

18. The one or more non-transitory computer-readable media of claim 15, wherein the processor-executable instructions is further caused to:
generate a sphere within the digital twin;
activate, based on a scope of the sphere, the one or more visual sensors of the plurality of visual sensors, one or more vehicles of the plurality of autonomously operated vehicles, or a combination thereof, wherein the one or more visual sensors or the one or more vehicles are disposed within a controllable radius of the sphere; and
deactivate, based on the scope of the sphere, the one or more visual sensors or the one or more vehicles disposed outside of the controllable radius of the sphere.

19. The one or more non-transitory computer-readable media of claim 15, wherein each of the plurality of visual sensors are remotely accessible by the user, such that the user can select any sensor of the plurality of sensors to view a portion of the digital twin in real-time.

20. The one or more non-transitory computer-readable media of claim 15, wherein the at least one processor is further caused to:
initiate a corrective action associated with a vehicle of the plurality of autonomously operated vehicles, wherein the corrective action assigns a new waypoint to the vehicle.
